(19) United States
(12) Patent Application Publication
(10) Pub. No.: US 2011/0174957 A1
(43) Pub. Date: Jul. 21, 2011

(54) RADIATION DETECTION ELEMENT

(75) Inventor: Yoshihiro OKADA, Kanagawa (JP)

(73) Assignee: FUJIFILM CORPORATION, Tokyo (JP)

(21) Appl. No.: 12/962,247

(22) Filed: Dec. 7, 2010

(30) Foreign Application Priority Data
Jan. 15, 2010 (JP) 2010-007063

(51) Int. Cl. H01L 27/146

(52) U.S. Cl. 250/208.1

(57) ABSTRACT

The present invention provides a radiation detection element that may suppress variation in wiring load, and that may increase the arrangement pitch of connecting portions connected to external circuits. Namely, plural pixels are disposed in an inclined matrix within a detection region, and a signal line is disposed for every two pixel lines in a vertical direction.

### CROSS-REFERENCE TO RELATED APPLICATION

This application claims priority under 35 USC 119 from Japanese Patent Application No. 2010-007063, filed on Jan. 15, 2010 the disclosure of which is incorporated by reference herein.

### BACKGROUND OF THE INVENTION

1. Field of the Invention

The present invention relates to a radiation detection element. In particular, the present invention relates to a radiation detection element having plural pixels that are disposed in a matrix in a rectangular detection region, that accumulate charges generated by irradiation of radiation, and that includes switching elements to read out the accumulated charges.

2. Description of the Related Art

Recently, radiographic imaging devices using a radiation detection element, have been put into practice employing a radiographic imaging element of a FPD (flat panel detector), or the like. Such radiographic imaging elements have an X-ray sensitive layer disposed on a TFT (Thin Film Transistor) active matrix substrate, and are able to directly convert X-ray information into digital data. Such FPDs have the merit that, in comparison to with previous imaging plates, images can be more immediately checked and video images can also be checked. Consequently the introduction of FPDs is proceeding rapidly. Various types are proposed for such radiographic imaging elements. There are, for example, direct-conversion-type radiographic imaging elements that convert radiation directly to charge in a semiconductor layer, and accumulate the charge. There are also indirect-conversion-type radiographic imaging elements that first convert radiation into light with a scintillator, such as CsI:Tl, GOS (Gd₂O₂S:Tb) or the like, then convert the converted light into charge in a semiconductor layer and accumulate the charge.

In the radiation detection element, plural scan lines and plural signal lines are disposed to intersect each other. In the radiation detection element, pixels are provided in a matrix at the intersection portion of the plural scan lines and the plural signal lines. The plural scan lines and the plural signal lines are connected to an external circuit (for example, an amplifier integrated circuit (IC) or a gate IC) at a peripheral portion of the radiation detection element.

Japanese Patent Application Laid-Open (JP-A) No. 2003-264273 discloses a technology that facilitates the connection of the scan lines and the signal lines with an external circuit at a peripheral portion of a radiation detection element. According to this technology, as shown in FIG. 6, scan lines 101′ and signal lines 3′ are disposed to be inclined at an angle of 30° to 60°, to a substrate including an approximately rectangular detection region 30′ for detecting the irradiated radiation. This technology increases the arrangement pitch of connecting portions of the scan lines 101′ and the signal signals 3′ with the external circuit for 1/sin θ times.

However, when the scan lines and the signal lines are disposed to be inclined using the technology disclosed in JP-A No. 2003-264273, the variation of the wiring load of the scan lines and the signal lines increases in a central portion and in an end portion. This is because the length or the number of connected pixels of the scan lines and the signal lines is different in the central portion and the end portion of the detection region. Accordingly, when the variation of the wiring load of the scan lines and the signal lines increases, image quality and driving capability in the detection region may be insufficient.

### SUMMARY OF THE INVENTION

The present invention provides a radiation detection element that may suppress the variation of the wiring load, and may increase the arrangement pitch of connecting portions to connect with external circuits.

A first aspect of the present invention is a radiation detection element including: a plurality of pixels disposed in a matrix inclined in a first direction and a second direction intersecting with first direction, and disposed within a rectangular detection region where sides of the region extend in the first direction and the second direction, that accumulate charges generated by irradiation of radiation, and that include switching elements to read out the accumulated charges; a plurality of first lines, disposed one by one for each line of a plurality of pixels in the first direction, that are connected to the switching elements, and are supplied with one of a control signal to switch the switching elements or an electric signal according to the accumulated charges; and a plurality of second lines, disposed one by one for each pixel line in the second direction, that are connected to the switching elements, and are supplied with the other one of the control signal or the electric signal.

A radiation detection element of the invention includes pixels disposed in a matrix to be inclined to first direction and a second direction that intersects the first direction, in a rectangular detection region where sides extend in first direction and the second direction. The pixels accumulate charges that are generated due to irradiation of radiation. The pixels include switching elements to read out the accumulated charges.

In the first aspect of the invention, the first lines are disposed individually for every plural pixel lines with respect to first direction of the pixels. Each of the first line are connected to the switching element included in the each pixel in the plural pixel lines. The first lines are supplied with a control signal that switch the switching elements or an electric signal according to the accumulated charges. In the first aspect of the invention, each of the second lines is disposed to each pixel line with respect to the pixels in the second direction. The second lines are connected to the switching elements that are included in the each pixel of the pixel line, and are supplied with the other one of the control signal or the electric signal.

According to the first aspect of the invention, the plural pixels are disposed in the matrix to be inclined in the detection region, and the first lines are disposed individually for every plural pixels of first direction. According to the first aspect, the arrangement pitch of the connecting portions to connect the first lines and the external circuits may be increased.

According to the first aspect of the invention, the first lines are disposed along first direction of the detection region and the second lines are disposed along the second direction of the detection region. Accordingly, in the first aspect of the invention, the lengths of the first lines and the second lines in a central portion and an end portion of the detection region becomes approximately the same, and the difference in the number of connected pixels decreases. Therefore, according to the first aspect of the invention, the variation of the wiring load of the first lines and the second lines may be suppressed.

A second aspect of the invention, in the first aspect, each first line may be provided for every two pixel lines with respect to the first direction, and may be disposed to divert around pixels between the two pixel lines.

A third aspect of the invention, in the above aspects, the pixels disposed in the matrix may be inclined at an angle of 30° to 60° with respect to the first direction and the second direction.

A fourth aspect of the invention, in the third aspect, the pixels disposed in the matrix may be inclined at an angle of 45° with respect to the first direction and the second direction.

A fifth aspect of the invention, in the above aspects, each second line may be connected to one of a plurality of external circuits, the plurality of external circuits may be provided at both sides of the detection region in the second direction, at one side or the other side in the second direction.

A sixth aspect of the invention, in the fifth aspect, individual second line may be alternately connected to the external circuits at one side or the other side in the second direction.

A seventh aspect of the invention, in the fifth aspect, plural second lines may be alternately connected to the external circuits at one side or the other side in the second direction.

An eighth aspect of the invention, in the above aspects, the first lines may be connected to the external circuits at one side in the first direction.

According to the aspect of the present invention, the variation of the wiring load may be suppressed, and the arrangement pitch of the connecting portions to connect with the external circuits may be increased.

### BRIEF DESCRIPTION OF THE DRAWINGS

Exemplary embodiments of the present invention will be described in detail based on the following figures, wherein:

FIG. 1 is a diagram showing the entire configuration of a radiographic imaging device according to an exemplary embodiment of the invention;

FIG. 2 is a plan view showing the configuration of a radiation detection element according to the exemplary embodiment of the invention;

FIG. 3 is a cross-sectional view of the radiation detection element according to the exemplary embodiment of the invention;

FIG. 4 is a diagram showing the configuration of a radiation detection element according to an alternative exemplary embodiment;

FIG. 5 is a diagram showing the configuration of a radiation detection element according to an alternative exemplary embodiment; and

FIG. 6 is a diagram showing the configuration of a radiation detection element according to the related art.

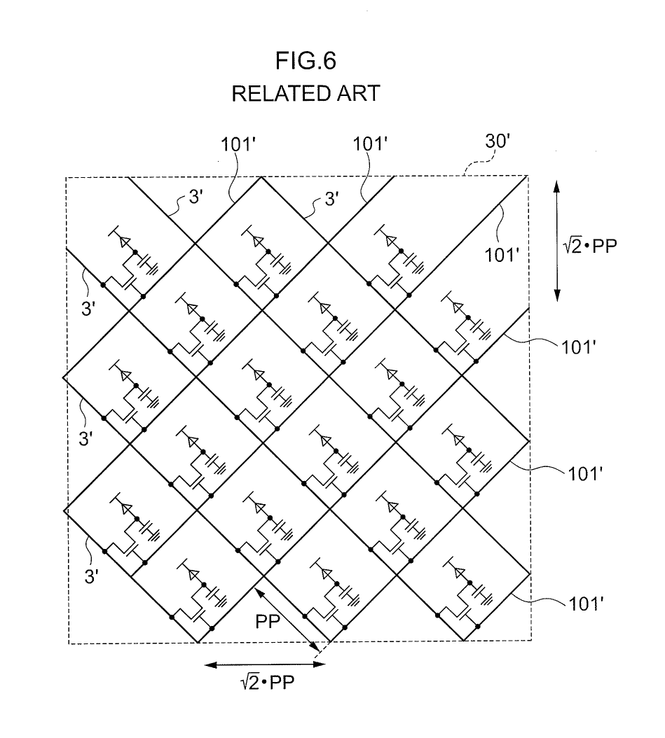

### DETAILED DESCRIPTION OF THE INVENTION

Hereinafter, exemplary embodiments of the present invention will be described with reference to the drawings. A case in which the present invention is applied to a direct-conversion-type radiation detection element 10 that directly converts radiation into charges, will be described.

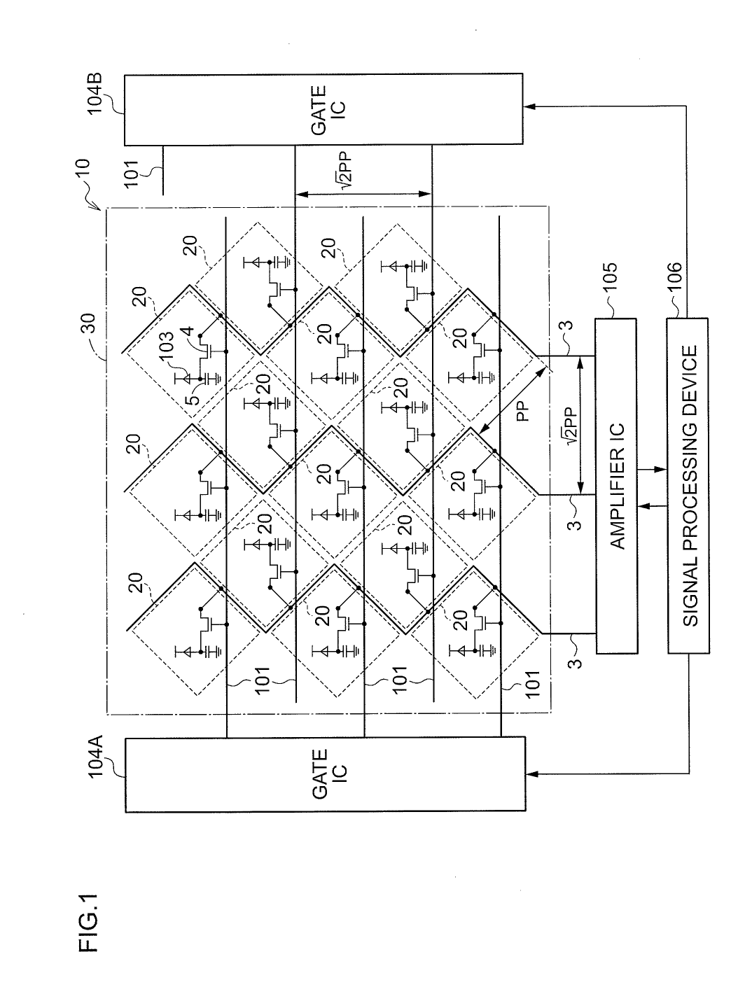

FIG. 1 shows the entire configuration of a radiographic imaging device 100 using a radiation detection element 10 according to the present exemplary embodiment.

As shown in FIG. 1, the radiographic imaging device 100 according to the present exemplary embodiment includes the radiation detection element 10 of the direct-conversion-type.

In the radiation detection element 10, a rectangular detection region 30 that has sides extending in first direction (horizontal direction of FIG. 1) and a second direction (vertical direction of FIG. 1) crossing first direction is provided. The radiation detection element 10 detects radiation that has been irradiated onto the detection region 30. In the detection region 30, plural pixels 20 are disposed in a matrix to be inclined to first direction and the second direction. In this exemplary embodiment, the pixels 20 are disposed in the matrix to be inclined to first direction and the second direction at an angle of 45°. Thereby, in the radiation detection element 10 according to this exemplary embodiment, the pixels 20 are disposed to be shifted in first direction by the ½ pixel width (half pitch), for each pixel line of first direction.

Each pixel 20 is configured to include a sensor section 103, a charge storage capacitor 5, and a TFT switch 4. The sensor section 103 receives the irradiated radiation and generates charges. The charge storage capacitor 5 accumulates the charges that are generated by the sensor section 103. The TFT switch 4 reads out the charges that are accumulated in the charge storage capacitor 5.

In the radiation detection element 10, a scan line 101 is individually disposed for each pixel line with respect to the first direction (horizontal direction of FIG. 1; hereinafter, also referred to as “scan line direction”) of the pixels 20 one by one. The scan line 101 is connected to the TFT switches 4 that are included in the pixels 20 of the pixel line in the scan line direction. The scan line 101 is supplied with a control signal to switch each TFT switch 4.

Signal lines 3 are disposed in the radiation detection element 10. Each signal line 3 is disposed between the two pixel lines to divert around the pixels 20, for every two pixel lines with respect to second direction (vertical direction of FIG. 1; hereinafter, also referred to as “signal line direction”) of the pixels 20. The signal line 3 is connected to the TFT switches 4 that are included in the pixels 20 of the two pixel lines. The signal line 3 is supplied with the charges accumulated in the charge storage capacitor 5 according to a switching state of each TFT switch 4.

In the radiation detection element 10 according to the present exemplary embodiment, plural amplifier ICs 105 that detect electric signals output form the individual signal lines 3 are provided on one end side of the signal line 3. A predetermined first number (for example, 256) of signal lines 3 are connected to one amplifier IC 105. In the radiation detection element 10 according to this exemplary embodiment, plural gate ICs 104A and 104B are provided. The plural gate ICs 104A and 104B output control signals to the scan lines 101 from both sides of the signal line direction with the detection region 30 therebetween to turn ON/OFF the TFT switches 4. In the scan lines 101, one end and the other end are alternately connected respectively to the gate ICs 104A and 104B. A predetermined second number (for example, 256) of scan lines 101 are connected to one of the gate ICs 104A or 104B. Note that, in FIG. 1, only one amplifier IC 105, one gate IC 104A, and one gate IC 104B are shown.

The amplifier IC 105 incorporates an amplifying circuit that amplifies an input electric signal, form each signal line 3. In the amplifier IC 105, the electric signal that is input from each signal line 3 is amplified by the amplifying circuit and is detected. Accordingly, the amplifier IC 105 detects the charge amount accumulated in each charge storage capacitor 5, as information of each of the pixels constituting an image.

A signal processing device 106 is connected to the amplifier IC 105 and the gate ICs 104A and 104B. The signal processing device 106 executes predetermined processing, such as noise removing processing, on the electric signal detected in the amplifier IC 105. In addition, the signal processing section 106 outputs a control signal indicating signal detection timing to the amplifier IC 105 and outputs a control signal indicating output timing of a scan signal to each of the gate ICs 104A and 104B.

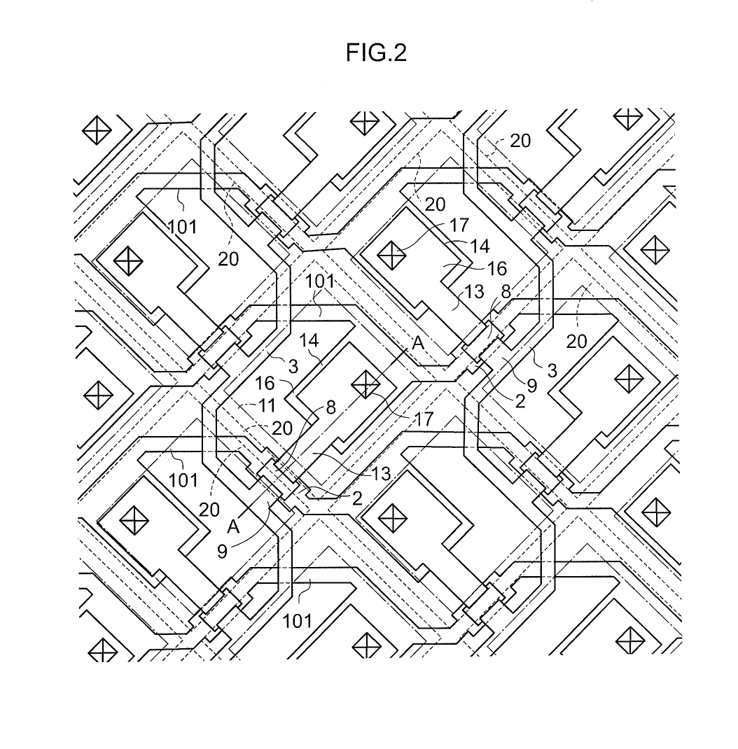

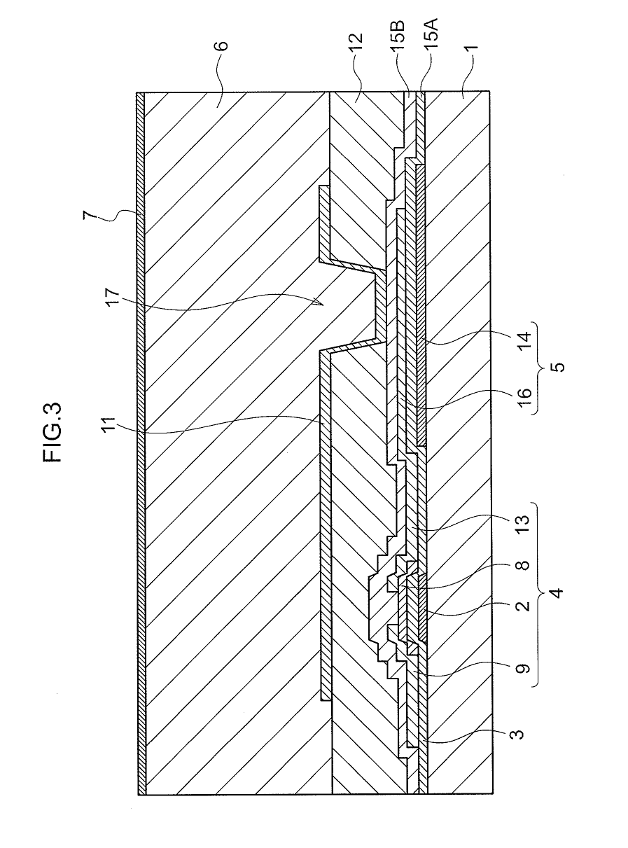

FIG. 2 is a plan view showing the structure of the radiation detection element 10 according to the present exemplary embodiment. FIG. 3 is a cross-sectional view taken along the line A-A of FIG. 2.

As shown in FIG. 3, in the radiation detection element 10, the scan lines 101 (refer to FIG. 2), storage capacitor lower electrodes 14, and gate electrodes 2 are formed on an insulating substrate 1. The scan lines 101 are disposed between the pixel lines in a meandering shape to divert around the pixels 20, and are disposed individually for each pixel line with respect to the scan line direction (horizontal direction of FIG. 2) of the pixels 20. The scan lines 101 are connected to the gate electrodes 2 that are formed in the upper side of each pixel 20 of the pixel line. In addition, the scan lines 101 are connected to the storage capacitor lower electrodes 14 that are formed in the lower side of the individual pixels 20 of the pixel line. A wiring layer (hereinafter, this wiring layer is also called a “first signal wiring layer”) where the scan lines 101, the storage capacitor lower electrodes 14, and the gate electrodes 2 are formed is formed using Al or Cu or a layered film that includes Al or Cu as a principal component. However, the material of the first signal wiring layer is not limited thereto.

An insulation film 15A is formed on one face of the first signal wiring layer. The locations of the insulation film 15A positioned over the gate electrodes 2 are employed as a gate insulation film in the TFT switches 4. The insulation film 15A is, for example, formed from SiNₓ or the like by, for example, Chemical Vapor Deposition (CVD) film forming.

An island shape of a semiconductor active layer 8 is formed on each of the gate electrodes 2 above the insulation film 15A. The semiconductor active layer 8 is a channel portion of the TFT switch 4 and is, for example, formed from an amorphous silicon film.

On the layers mentioned above, a source electrode 9 and a drain electrode 13 are formed. The wiring layer in which the source electrode 9 and the drain electrode 13 are formed also has the signal lines 3 (refer to FIG. 2) formed therein. Further, at the position that corresponds to the storage capacitor lower electrode 14 on the insulating film 15A, a storage capacitor upper electrode 16 is formed. The drain electrode 13 is connected to the storage capacitor upper electrode 16. The signal lines 3 are disposed between the two pixel lines in a meandering shape to divert around the pixels 20, and are disposed individually for every two pixel lines with respect to the signal line direction (vertical direction of FIG. 2) of the pixels 20. The signal lines 3 are connected to the source electrodes 9 that are included in each pixel 20 of the two pixel lines. A wiring layer (hereinafter, this wiring layer is also called a “second signal wiring layer”) where the source electrode 9, the drain electrode 13, the signal line 3, and the storage capacitor upper electrode 16 are formed, is formed by using Al or Cu or a layered film that includes Al or Cu as a principal component. However, the material of the second signal wiring layer is not limited thereto. Between the source electrode 9 and the drain electrode 13 and the semiconductor active layer 8, an impurity doped semiconductor layer (not shown in the drawings) made of impurity doped amorphous silicon is formed. Thereby, the TFT switch 4 for switching is configured. Note that the source electrodes 9 and the drain electrodes 13 of the of the TFT switches 4 are of opposite polarity to that of the charge collected and accumulated with the lower electrode 11, described below.

A TFT protective film 15B is formed on almost the entire surface (almost the entire region) of a region which covers the second signal wiring layer and in which the pixels on the substrate 1 are provided. The TFT protective film 15B is formed, for example, from SiNₓ or the like by, for example, Chemical Vapor Deposition (CVD) film forming.

A coating type interlayer insulating film 12 is formed on the TFT protective film 15B. The interlayer insulating film 12 is formed from a photosensitive organic material of low permittivity (dielectric constant of ∈r=2 to 4) (for example, a material such as a positive-working photosensitive acrylic resin: a base polymer of a copolymer of methacrylic acid and glycidyl methacrylate, into which a naphthoquinone-diazido positive-working photosensitive agent has been mixed). The thickness of the interlayer insulating film 12 is 1 to 4 μm.

In the radiation detection element 10 according to the present exemplary embodiment, capacitance between the metal layers disposed below and above the intermediate insulation film 12 can be suppressed low by provision of the intermediate insulation film 12. Furthermore, generally such materials also have functionality as a flattening layer, and exhibit the effect of flattening out steps in the layer below. In the radiation detection element 10 according to the present exemplary embodiment, contact holes 17 are formed in the intermediate insulation film 12 and the TFT protection layer 15B at positions facing the storage capacitor upper electrode 16.

On the interlayer insulating film 12, the lower electrode 11 of the sensor section 103 is formed for each pixel 20 to fill each contact hole 17 and to cover the pixel region. The lower electrode 11 is made of an amorphous transparent conductive oxide film (ITO), and is connected to the storage capacitor upper electrode 16 through the contact hole 17. Therefore, the lower electrode 11 and the TFT switch 4 are electrically connected through the storage capacitor upper electrode 16.

In almost the entire surface of the pixel region on the lower electrode 11 where the pixels 20 on the substrate 1 are provided, a semiconductor layer 6 is formed. The semiconductor layer 6 is irradiated with radiation such as X-rays and generates the charges (electron-hole pairs) therein. Namely, the semiconductor layer 6 has conductivity and converts image information based on X-rays into charge information. The semiconductor layer 6 is formed of amorphous selenium (a-Se) using selenium as a principal component. Note that the term principal component means a component that has a content rate of 50% or more.

On the semiconductor layer 6, an upper electrode 7 is formed. The upper electrode 7 is connected to a bias power supply (not shown in the drawings). The upper electrode 7 is supplied with a bias voltage, from the bias power supply.

Next, the operation of the radiographic imaging device 100 that has the above configuration will be described.

Firstly, the bias voltage is applied between the upper electrode 7 and the storage capacitor lower electrode 14. In this state, if the X-rays are irradiated onto the semiconductor layer 6, the charges (electron-hole pairs) are generated in the semiconductor layer 6.

The semiconductor layer 6 and the charge storage capacitor 5 are configured to be electrically connected in series. Accordingly, the electrons that are generated in the semiconductor layer 6 moves to a plus electrode side, and the holes move to the minus electrode side. When detecting an image, an OFF signal (0 V) is output from the gate ICs 104A and 104B to all of the scan lines 101. Accordingly, a negative bias is applied to the gate electrode 2 of the TFT switch 4. Due thereto, each TFT switch 4 is maintained in an OFF state, and the electrons that are generated in the semiconductor layer 6 are collected by the lower electrode 11 and are accumulated in the charge storage capacitor 5.

When reading out an image, an ON signal is sequentially output from the gate ICs 104A and 104B to the scan lines 101 one by one. Due thereto, an ON signal (+10 to 20 V) is sequentially applied to the gate electrode 2 of the TFT switch 4 through the scan line 101. Accordingly, the TFT switches 4 of the individual pixels 20 of the individual pixel lines in the scan line direction are sequentially turned ON for each column. As a result, an electric signal according to the charge amount accumulated in the charge storage capacitors 5 of the individual pixels 20 for each column is output to the signal lines 3. In the present exemplary embodiment, each scan line 101 is connected to the gate electrode 102 included in each pixel 20 within the pixel lines in the upper side of the detection region. Together therewith, each scan line 101 is connected to the storage capacitor lower electrode 14 included in each pixel 20 within the pixel line in the lower side of the detection region. Due thereto, the gate ICs 104A and 104B outputs an ON signal from the lower side of the signal line direction through each scan line 101. Accordingly, when the ON signal is output to the scan lines 101 of the n^{th} pixel line in the scan line direction and the charges are read out, an OFF signal is output to the scan lines 101 of the (n+1)^{th} pixel line. Therefore, in the present exemplary embodiment, the potential of the storage capacitor lower electrode 14 of the charge storage capacitor 5 may be constantly maintained.

The amplifier IC 105 detects the charge amount accumulated in the charge storage capacitor 5 of each sensor section 103 as information of the pixels constituting the image, on the basis of the electric signal output through each signal line 3. Thereby, the radiation detection element 10 may obtain image information that represents the irradiated X-rays.

In the radiation detection element 10 according to the present exemplary embodiment, the matrix arrangement of the pixels 20 is inclined at 45°. In the radiation detection element 10 according to the present exemplary embodiment, the signal line 3 is disposed for every two pixel lines in the signal line direction. Accordingly, when the pixel interval of the pixels 20 in the matrix arrangement is denoted as PP, the arrangement pitch of the signal lines 3 in the connecting portions with the amplifier IC 105 in the peripheral portion of the radiation detection element 10 becomes 1.41 pp. This is because the pixel interval PP is increased to 1/sin 45° (=√2) times, that is, 1.41 times. Due thereto, according to the present exemplary embodiment, the signal lines 3 and the amplifier IC 105 may be easily connected to each other.

Meanwhile, the two scan lines 101 need to be provided within the interval of 1.41 PP. However, in the present exemplary embodiment, the gate ICs 104A and 104B are provided on both sides of the scan line direction and the scan lines 101 are alternately connected to the gate ICs 104A and 104B. Accordingly, the arrangement pitch of the scan lines 101 in the connecting portions with the gate ICs 104A and 104B in the peripheral portion of the radiation detection element 10 becomes 1.41 PP. Due thereto, in the present exemplary embodiment, the scan lines 101 and the gate ICs 104A and 104B may be easily connected to each other.

According to the present exemplary embodiment, the signal lines 3 and the scan lines 101 are disposed along the sides of first direction and the second direction of the detection region 30. For this reason, in this exemplary embodiment, the length difference of the scan lines 101 and the signal lines 3 or the difference of the number of connected pixels 20 in the central portion and the end portion of the detection region 30 may be suppressed low. Therefore, in the present exemplary embodiment, the variation of the wiring load of the scan lines 101 and the signal lines 3 in the central portion and the end portion may be suppressed low.

In the radiation detection element 10 according to the present exemplary embodiment, the gate ICs 104A and 104B are provided on both sides of the scan line direction. In the radiation detection element 10 according to the present exemplary embodiment, the amplifier IC 105 is provided on one side of the signal line direction and the external circuits are not connected on the other side of the signal line direction. The radiation detection element 10 may capture an image without providing the external circuits on one side. Accordingly, in the radiation detection element 10 according to the present exemplary embodiment, the detection region 30 may be made to be close to the end portion of the substrate 1 on one side where the external circuits are not provided. In mammography, an image of a portion close to the base of the breast needs to be captured, and the detection region 30 needs to be close to the end portion of the substrate 1. For this reason, the radiation detection element 10 according to the present exemplary embodiment may capture an image of the portion close to the base of the breast, by configuring the side where the external circuits are not provided as the breast side.

In the radiation detection element 10 according to the present exemplary embodiment, the positions of the pixels 20 of the pixel line in a row direction for every other column is shifted by the ½ pixel width in the row direction. Accordingly, in the radiation detection element 10 according to the present exemplary embodiment, data of the pixels 20 of each pixel line shifted in the row direction becomes data at the positions shifted by the ½ pixel width from the normal positions. However, the data may be generated as data at the normal positions by executing image processing such as interpolation processing in the signal processing device 106. As an example of this image processing, a radiation image reading method is disclosed in JP-A No. 2000-244733.

In above the exemplary embodiment, a case in which the matrix arrangement of the pixels 20 is inclined at 45°, has been described. However, the inclined angle θ is not limited to 45°, and the angle θ may be an arbitrary angle from 30° to 60°. If the inclined angle θ is set to the angle from 30° to 60°, the arrangement pitch of the signal lines 3 in the connecting portions with the external circuits in the peripheral portion of the radiation detection element 10 can be increased to about 1.15 to 2 times. Accordingly, connection with the external circuits may be easily performed.

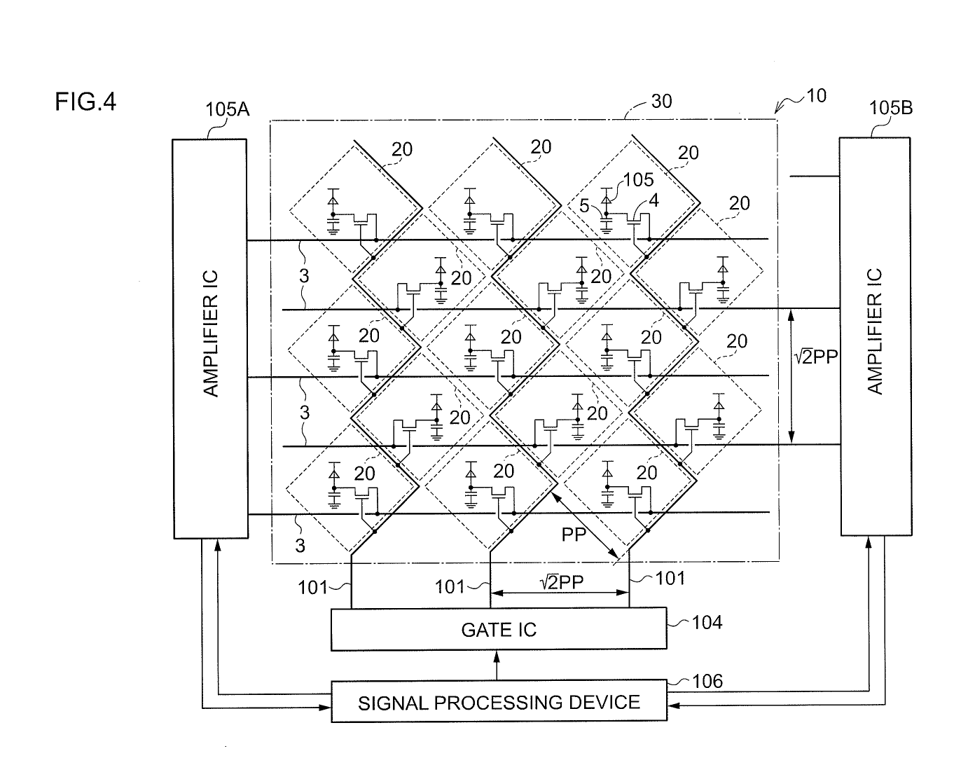

In the above exemplary embodiment, a case in which the signal line 3 is disposed for every two pixel lines with respect to first direction (vertical direction of FIG. 1) of the pixels 20, the plural amplifier ICs 105 to detect the electric signal output to each signal line 3 are provided on one end side of first direction, the scan line 101 is disposed for each pixel line with respect to the second direction (horizontal direction of FIG. 1) of the pixels 20, the gate ICs 104A and 104B are provided on both sides of the second direction, and the scan lines 101 are alternately connected to the gate ICs 104A and 104B one by one, has been described. However, the present invention is not limited thereto. For example, as shown in FIG. 4, in an alternative exemplary embodiment, the configuration of the signal line 3 and the scan line 101 may be reversed, and the signal line 3 may be disposed for each pixel line with respect to the second direction (horizontal direction of FIG. 4) of the pixels 20. In this alternative exemplary embodiment, the signal lines 3 may be connected to the source electrodes 9 of the TFT switches 4 that are provided in each pixel 20 of each pixel lines 20 to let the charges accumulated in the charge storage capacitor 5 flows in accordance to the switching state of the TFT switches 4. In addition, in the alternative exemplary embodiment, amplifier ICs 105A and 105B may be provided on both sides of the second direction and the signal lines 3 may be alternately connected to the amplifier ICs 105A and 105B one by one. Further in the alternative exemplary embodiment, the scan line 101 may be disposed for every two pixel lines with respect to first direction (vertical direction of FIG. 4) of the pixels 20. In the exemplary embodiment, the scan lines 101 may be connected to the gate electrodes 2 of the TFT switches 4 that are provided in the individual pixels 20 of the two pixel lines. In addition, in this alternative exemplary embodiment, a gate IC 104 may be provided on one end side of first direction, each scan line 101 may be connected, and an image may be read for every two pixel lines of first direction.

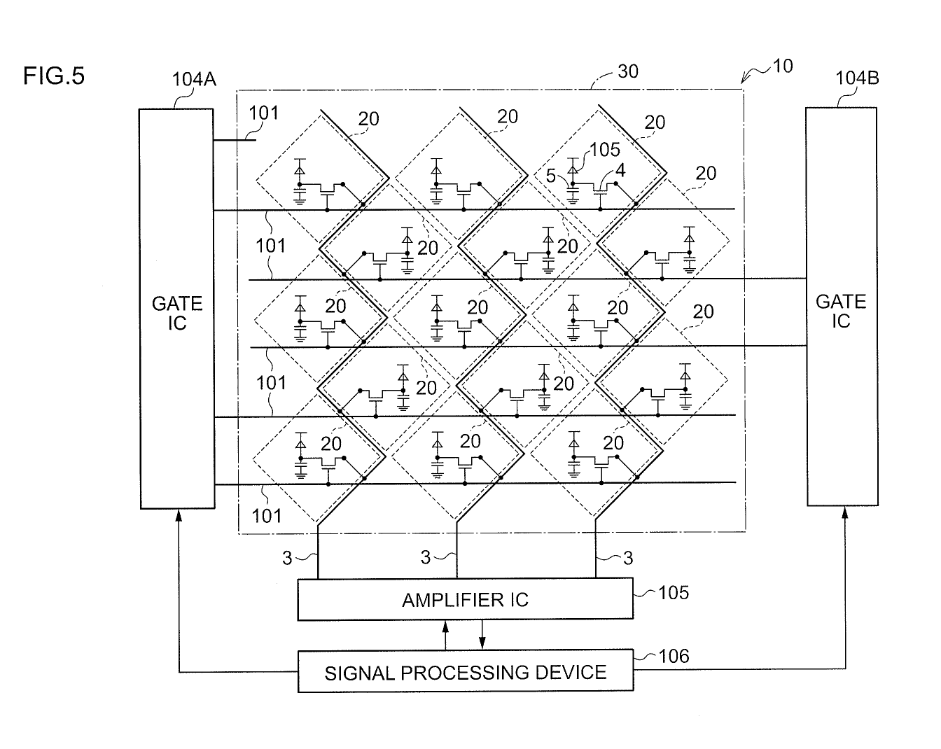

In the above exemplary embodiment, a case in which the scan lines 101 are alternately connected to the gate ICs 104A and 104B one by one, has been described. However, the present invention is not limited thereto. For example, as shown in FIG. 5, in an alternative exemplary embodiment, the plural scan lines 101 (two scan lines in FIG. 5) may be alternately connected to the gate ICs 104A and 104B. In this alternative exemplary embodiment, reading of a specific range may be performed by one gate IC by connecting the plural scan lines to the gate IC 104A. Accordingly, this alternative exemplary embodiment may divide a read out range into plural blocks.

In the above exemplary embodiments, a case in which the invention is applied to the radiation detection element 10 of the direct-conversion-type, has been described. However, the invention may be applied to the radiation detection element 10 of the indirect-conversion-type.

In the above exemplary embodiments, a case in which the present invention is applied to the radiographic imaging device 100 which detects the X-rays as the detection object radiation, has been described. However, the present invention is not limited thereto. For example, the radiation that is the detection object may be visible light, ultraviolet rays, infrared rays or gamma rays.

In the above exemplary embodiments, a case in which the radiation detection element 10 includes the charge storage capacitor 5 provided for each pixel 20 is described. However, when the lower electrode 11 has the capacitance enabling sufficient charge accumulation, the charge storage capacitor 5 may not be formed in each pixel 20.

The configuration of the radiographic imaging device 100 and the configuration of the radiation detection element 10 that are described in the above exemplary embodiments are only an example. Various changes may be made within a range that does not depart from the spirit and scope of the present invention.

What is claimed is:

1. A radiation detection element comprising:
a plurality of pixels disposed in a matrix inclined in a first direction and a second direction intersecting with first direction, and disposed within a rectangular detection region where sides of the region extend in the first direction and the second direction, that accumulate charges generated by irradiation of radiation, and that include switching elements to read out the accumulated charges;
a plurality of first lines, disposed one by one for each line of a plurality of pixels in the first direction, that are connected to the switching elements, and are supplied with one of a control signal to switch the switching elements or an electric signal according to the accumulated charges; and
a plurality of second lines, disposed one by one for each pixel line in the second direction, that are connected to the switching elements, and are supplied with the other one of the control signal or the electric signal.

2. The radiation detection element of claim 1, wherein each first line is provided for every two pixel lines with respect to the first direction, and is disposed to divert around pixels between the two pixel lines.

3. The radiation detection element of claim 1, wherein the pixels disposed in the matrix are inclined at an angle of 30° to 60° with respect to the first direction and the second direction.

4. The radiation detection element of claim 3, wherein the pixels disposed in the matrix are inclined at an angle of 45° with respect to the first direction and the second direction.

5. The radiation detection element of claim 1, wherein each second line is connected to one of a plurality of external circuits, the plurality of external circuits provided at both sides of the detection region in the second direction, at one side or the other side in the second direction.

6. The radiation detection element of claim 5, wherein individual second line are alternately connected to the external circuits at one side or the other side in the second direction.

7. The radiation detection element of claim 5, wherein plural second lines are alternately connected to the external circuits at one side or the other side in the second direction.

8. The radiation detection element of claim 5, wherein the first lines are connected to the external circuits at one side in the first direction.
